(19) United States
(12) Patent Application Publication
(10) Pub. No.: US 2015/0180206 A1
(43) Pub. Date: Jun. 25, 2015

(54) VERTICAL CAVITY SURFACE EMITTING LASER AND ATOMIC OSCILLATOR

(71) Applicant: Seiko Epson Corporation, Tokyo (JP)

(72) Inventor: Yasutaka IMAI, Suwa (JP)

(21) Appl. No.: 14/576,823

(22) Filed: Dec. 19, 2014

(30) Foreign Application Priority Data
Dec. 20, 2013 (JP) 2013-263470

(51) Int. Cl. H01S 5/183

(52) U.S. Cl. CPC H01S 5/183

(57) ABSTRACT

A vertical cavity surface emitting laser includes: a substrate; and a laminated body which is provided over the substrate, wherein, in a plan view, the laminated body includes a first distortion imparting portion, a second distortion imparting portion, and a resonance portion which is provided between the first distortion imparting portion and the second distortion imparting portion and resonates light generated in the laminated body, and the laminated body includes a first mirror layer which is provided over the substrate, an active layer which is provided over the first mirror layer, a second mirror layer which is provided over the active layer, and a contact layer which is provided over the second mirror layer of the resonance portion, except for a portion over the second mirror layer of the first distortion imparting portion and for a portion over the second mirror layer of the second distortion imparting portion.

### BACKGROUND

1. Technical Field

The present invention relates to a vertical cavity surface emitting laser and an atomic oscillator.

2. Related Art

The vertical cavity surface emitting laser (VCSEL) is, for example, used as a light source of the atomic oscillator using coherent population trapping (CPT) which is one of the quantum interference effects.

In the vertical cavity surface emitting laser, a resonator generally has an isotropic structure, and accordingly it is difficult to control a polarization direction of laser light emitted from the resonator. JP-A-11-54838, for example, discloses a vertical cavity surface emitting laser which generates distortion in a resonator by a distortion imparting portion and causes double refraction to occur, so as to stabilize a polarization direction of laser light obtained by laser oscillation.

However, in the vertical cavity surface emitting laser disclosed in JP-A-11-54838, the distortion imparting portion is configured to include a contact layer connected to an upper electrode. Accordingly, in the vertical cavity surface emitting laser disclosed in JP-A-11-54838, parasitic capacitance may be increased and characteristics thereof may be degraded.

### SUMMARY

An advantage of some aspects of the invention is to provide a vertical cavity surface emitting laser which can decrease parasitic capacitance. Another advantage of some aspects of the invention is to provide an atomic oscillator including the vertical cavity surface emitting laser.

An aspect of the invention is directed to a vertical cavity surface emitting laser including: a substrate; and a laminated body which is provided over the substrate, in which, in a plan view, the laminated body includes a first distortion imparting portion, a second distortion imparting portion, and a resonance portion which is provided between the first distortion imparting portion and the second distortion imparting portion and resonates light generated in the laminated body, and the laminated body includes a first mirror layer which is provided over the substrate, an active layer which is provided over the first mirror layer, a second mirror layer which is provided over the active layer, and a contact layer which is provided over the second mirror layer of the resonance portion, except for a portion over the second mirror layer of the first distortion imparting portion and a portion over the second mirror layer of the second distortion imparting portion.

According to the vertical cavity surface emitting laser, it is possible to decrease capacitance of the current constriction layer, and therefore, it is possible to decrease parasitic capacitance.

In the description according to the invention, for example, when a term “over” is used in a sentence such as “to form a specific element (hereinafter, referred to as a “B”) over another specific element (hereinafter, referred to as an “A”)”, the term “over” is used to include a case of forming the B directly on the A and a case of forming the B on the A with another element interposed therebetween.

In the vertical cavity surface emitting laser according to the aspect of the invention, the vertical cavity surface emitting laser may further include an electrode which forms ohmic contact with the contact layer.

According to the vertical cavity surface emitting laser with this configuration, it is possible to decrease the parasitic capacitance.

In the vertical cavity surface emitting laser according to the aspect of the invention, the laminated body may include a current constriction layer which is provided between the first mirror layer and the second mirror layer.

According to the vertical cavity surface emitting laser with this configuration, it is possible to decrease the parasitic capacitance.

Another aspect of the invention is directed to an atomic oscillator including: the vertical cavity surface emitting laser according to the aspect of the invention.

According to the atomic oscillator, since the atomic oscillator includes the vertical cavity surface emitting laser according to the aspect of the invention, it is possible to obtain excellent characteristics.

### BRIEF DESCRIPTION OF THE DRAWINGS

The invention will be described with reference to the accompanying drawings, wherein like numbers reference like elements.

FIG. 1 is a plan view schematically showing a vertical cavity surface emitting laser according to the embodiment.

FIG. 2 is a cross-sectional view schematically showing a vertical cavity surface emitting laser according to the embodiment.

FIG. 3 is a plan view schematically showing a vertical cavity surface emitting laser according to the embodiment.

FIG. 4 is a cross-sectional view schematically showing a vertical cavity surface emitting laser according to the embodiment.

FIG. 5 is a cross-sectional view schematically showing a vertical cavity surface emitting laser according to the embodiment.

FIG. 6 is a view for illustrating parasitic capacitance of a vertical cavity surface emitting laser.

FIG. 7 is a view for illustrating parasitic capacitance of a vertical cavity surface emitting laser.

FIG. 8 is a cross-sectional view schematically showing a manufacturing step of a vertical cavity surface emitting laser according to the embodiment.

FIG. 9 is a cross-sectional view schematically showing a manufacturing step of a vertical cavity surface emitting laser according to the embodiment.

FIG. 10 is a cross-sectional view schematically showing a manufacturing step of a vertical cavity surface emitting laser according to the embodiment.

FIG. 11 is a cross-sectional view schematically showing a manufacturing step of a vertical cavity surface emitting laser according to the embodiment.

FIG. 12 is a cross-sectional view schematically showing a manufacturing step of a vertical cavity surface emitting laser according to the embodiment.

FIG. 13 is a cross-sectional view schematically showing a manufacturing step of a vertical cavity surface emitting laser according to the embodiment.

FIG. 14 is a cross-sectional view schematically showing a manufacturing step of a vertical cavity surface emitting laser according to the embodiment.

FIG. 15 is a cross-sectional view schematically showing a manufacturing step of a vertical cavity surface emitting laser according to a modification example of the embodiment.

FIG. 16 is a cross-sectional view schematically showing a manufacturing step of a vertical cavity surface emitting laser according to a modification example of the embodiment.

FIG. 17 is a cross-sectional view schematically showing a manufacturing step of a vertical cavity surface emitting laser according to a modification example of the embodiment.

FIG. 18 is a cross-sectional view schematically showing a manufacturing step of a vertical cavity surface emitting laser according to a modification example of the embodiment.

FIG. 19 is a functional block diagram of an atomic oscillator according to the embodiment.

FIG. 20 is a view showing frequency spectra of resonant light.

FIG. 21 is a view showing a relationship between Λ-shaped three level models of an alkaline metal atom, a first sideband wave, and a second sideband wave.

### DESCRIPTION OF EXEMPLARY EMBODIMENTS

Hereinafter, preferred embodiments of the invention will be described in detail with reference to the drawings. The embodiments described below are not intended to unduly limit the contents of the invention disclosed in the aspects. All of the configurations described below are not limited to the essential constituent elements of the invention.

### 1. Vertical Cavity Surface Emitting Laser

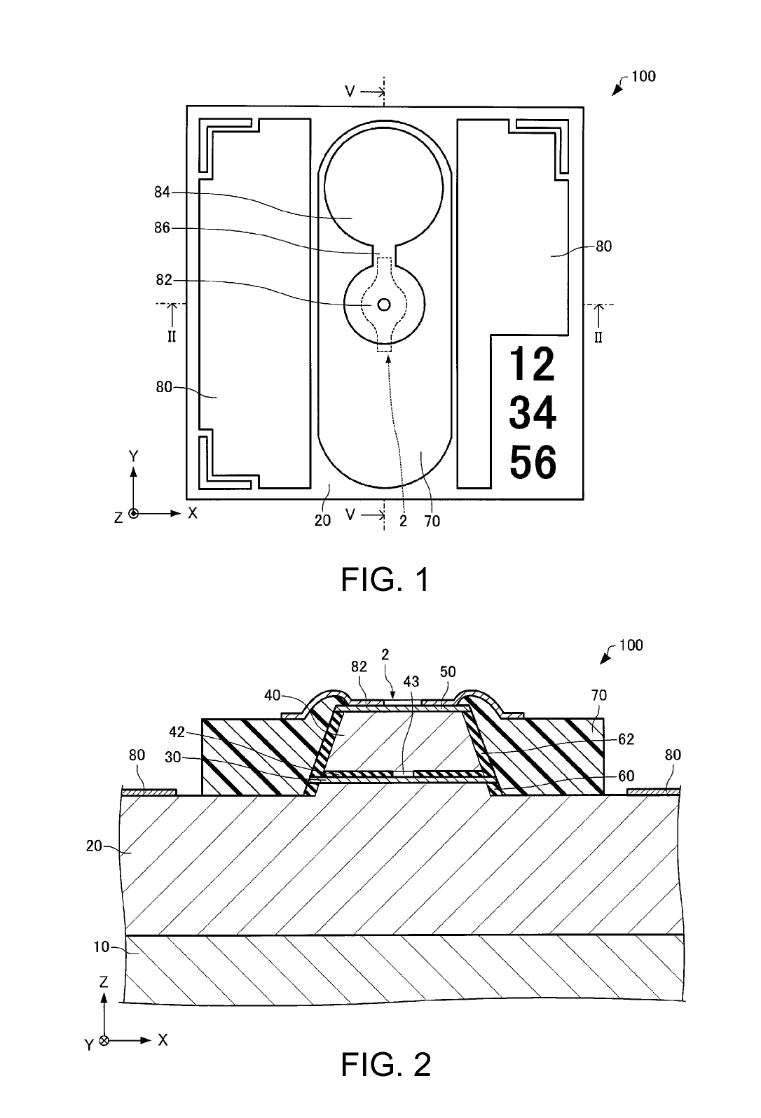

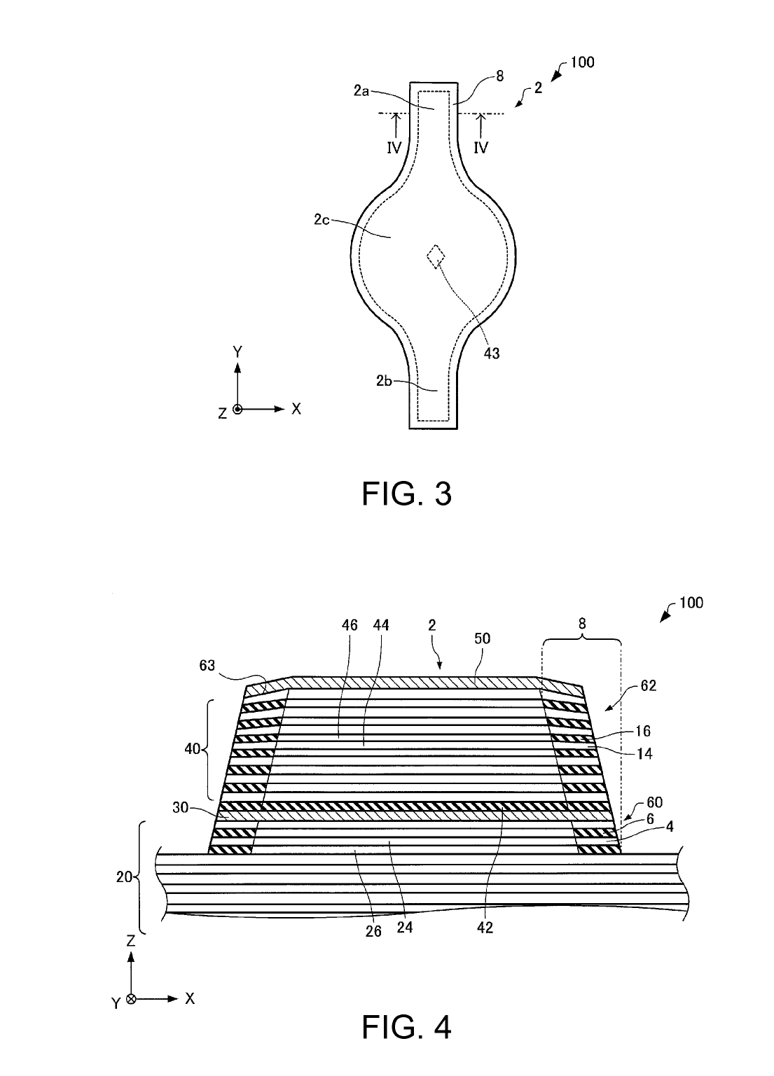

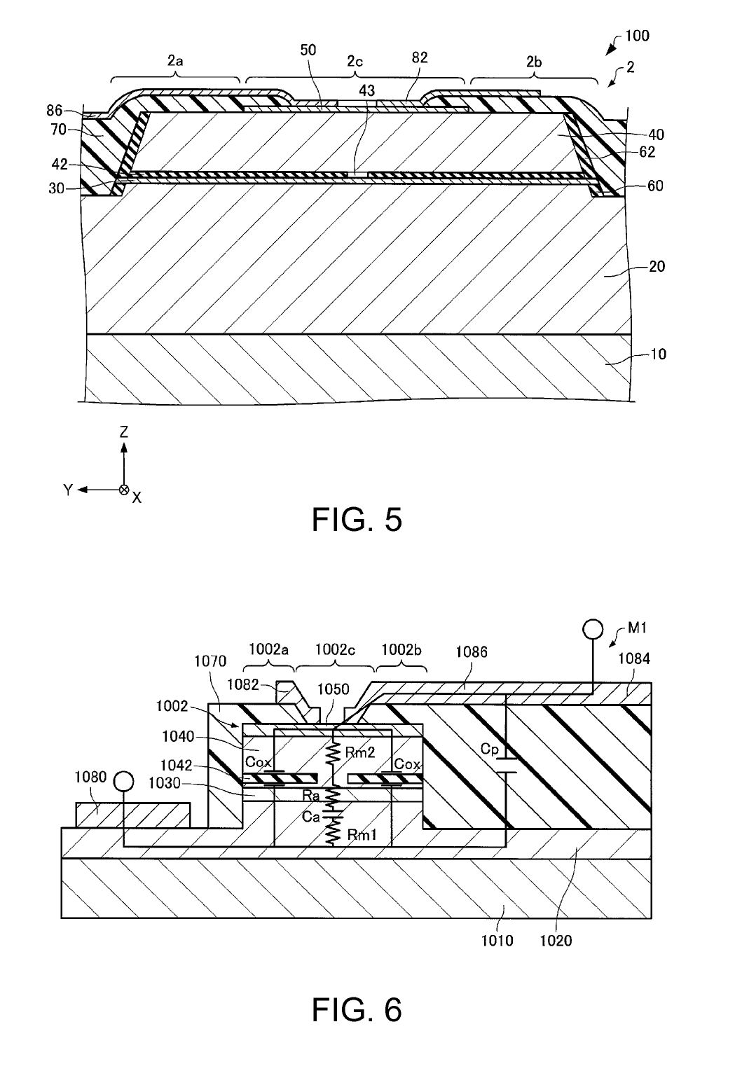

First, a vertical cavity surface emitting laser according to the embodiment will be described with reference to the drawings. FIG. 1 is a plan view schematically showing a vertical cavity surface emitting laser 100 according to the embodiment. FIG. 2 is a cross-sectional view which is taken along line II-II of FIG. 1 and schematically shows the vertical cavity surface emitting laser 100 according to the embodiment. FIG. 3 is a plan view schematically showing the vertical cavity surface emitting laser 100 according to the embodiment. FIG. 4 is a cross-sectional view which is taken along line IV-IV of FIG. 3 and schematically shows the vertical cavity surface emitting laser 100 according to the embodiment. FIG. 5 is a cross-sectional view which is taken along line V-V of FIG. 1 and schematically shows the vertical cavity surface emitting laser 100.

For the sake of convenience, FIGS. 2 and 5 show a simplified laminated body 2. In FIG. 3, members other than the laminated body 2 of the vertical cavity surface emitting laser 100 are omitted. FIGS. 1 to 5 show an X axis, a Y axis, and a Z axis as three axes orthogonal to each other.

As shown in FIGS. 1 to 5, the vertical cavity surface emitting laser 100 includes a substrate 10, a first mirror layer 20, an active layer 30, a second mirror layer 40, a current constriction layer 42, a contact layer 50, first areas 60, second areas 62, a resin layer (insulation layer) 70, first electrodes 80, and second electrodes 82.

The substrate 10 is, for example, a first conductive (for example, n-type) GaAs substrate.

The first mirror layer 20 is formed on the substrate 10. The first mirror layer 20 is a first conductive semiconductor layer. As shown in FIG. 4, the first mirror layer 20 is a distribution Bragg reflection (DBR) type mirror in which high refractive index layers 24 and low refractive index layers 26 are laminated onto each other. The high refractive index layer 24 is, for example, an n-type Al_{0.12}Ga_{0.88}As layer on which silicon is doped. The low refractive index layer 26 is, for example, an n-type Al_{0.9}Ga_{0.1}As layer on which silicon is doped. The number (number of pairs) of laminated high refractive index layers 24 and low refractive index layers 26 is, for example, 10 pairs to 50 pairs, specifically, 40.5 pairs.

The active layer 30 is provided on the first mirror layer 20. The active layer 30, for example, has a multiple quantum well (MQW) structure in which three layers having a quantum well structure configured with an i-type In_{0.06}Ga_{0.94}As layer and an i-type Al_{0.3}Ga_{0.7}As layer are overlapped.

The second mirror layer 40 is formed on the active layer 30. The second mirror layer 40 is a second conductive (for example, p-type) semiconductor layer. The second mirror layer 40 is a distribution Bragg reflection (DBR) type mirror in which high refractive index layers 44 and low refractive index layers 46 are laminated onto each other. The high refractive index layer 44 is, for example, a p-type Al_{0.12}Ga_{0.88}As layer on which carbon is doped. The low refractive index layer 46 is, for example, a p-type Al_{0.9}Ga_{0.1}As layer on which carbon is doped. The number (number of pairs) of laminated high refractive index layers 44 and low refractive index layers 46 is, for example, 3 pairs to 40 pairs, specifically, 20 pairs.

The second mirror layer 40, the active layer 30, and the first mirror layer 20 configure a vertical resonator-type pin diode. When a forward voltage of the pin diode is applied between the electrodes 80 and 82, recombination between electrons and positive holes occurs in the active layer 30, and the light emitting occurs. The light generated in the active layer 30 reciprocates between the first mirror layer 20 and the second mirror layer 40 (multiple reflection), the induced emission occurs at that time, and the intensity is amplified. When an optical gain exceeds an optical loss, laser oscillation occurs, and the laser light is emitted in a vertical direction (a lamination direction of the first mirror layer 20 and the active layer 30) from the upper surface of the contact layer 50.

The current constriction layer 42 is provided between the first mirror layer 20 and the second mirror layer 40. In the example shown in the drawing, the current constriction layer 42 is provided on the active layer 30. The current constriction layer 42 can also be provided in the first mirror layer 20 or the second mirror layer 40. In this case as well, the current constriction layer 42 is assumed to be provided between the first mirror layer 20 and the second mirror layer 40. The current constriction layer 42 is an insulation layer in which an opening 43 is formed. The current constriction layer 42 can prevent spreading of the current injected to a vertical resonator by the electrodes 80 and 82 in a planar direction (direction orthogonal to the lamination direction of the first mirror layer 20 and the active layer 30).

The contact layer 50 is provided on the second mirror layer 40. As shown in FIG. 5, the contact layer 50 is provided on the second mirror layer 40 of the resonance portion 2c, except for a portion on the second mirror layer 40 of the first distortion imparting portion 2a and a portion on the second mirror layer 40 of the second distortion imparting portion 2b. That is, the contact layer 50 is only provided on the upper surface of the resonance portion 2c. The contact layer 50 is a second conductive semiconductor layer. Specifically, the contact layer 50 is a p-type GaAs layer on which carbon is doped.

As shown in FIG. 4, the first areas 60 are provided on lateral portions of the first mirror layer 20 configuring the laminated body 2. The first areas 60 include a plurality of oxide layers 6 which are provided to be connected to the first mirror layer 20 (in the example shown in the drawing, a part of the first mirror layer 20). Specifically, the first areas 60 are configured with the oxide layers 6 obtained by oxidizing layers connected to the low refractive index layers (for example, Al_{0.9}Ga_{0.1}As layers) configuring the first mirror layer 20, and layers 4 connected to the high refractive index layers 24 (for example, Al_{0.12}Ga_{0.88}As layers) configuring the first mirror layer 20 which are laminated on each other.

The second areas 62 are provided on lateral portions of the second mirror layer 40 configuring the laminated body 2. The second areas 62 include a plurality of oxide layers 16 which are provided to be connected to the second mirror layer 40. Specifically, the second areas 62 are configured with the oxide layers 16 obtained by oxidizing layers connected to the low refractive index layers 46 (for example, Al_{0.9}Ga_{0.1}As layers) configuring the second mirror layer 40, and layers 14 connected to the high refractive index layers 44 (for example, Al_{0.12}Ga_{0.88}As layers) configuring the second mirror layer 40 which are laminated on each other. In a plan view (when seen from the lamination direction of the first mirror layer 20 and the active layer 30), oxide areas 8 are configured by the first areas 60 and the second areas 62.

The first mirror layer 20, the active layer 30, the second mirror layer 40, the current constriction layer 42, the contact layer 50, the first areas 60, and the second areas 62 configure the laminated body 2. In the example shown in FIGS. 1 and 2, the laminated body 2 is surrounded with the resin layer 70.

In the example shown in FIG. 3, in a plan view, a length of the laminated body 2 in a Y axis direction is greater than a length of the laminated body 2 in an X axis direction. That is, a longitudinal direction of the laminated body 2 is the Y axis direction. In a plan view, the laminated body 2 is, for example, symmetrical about a virtual straight line which passes through the center of the laminated body 2 and is parallel to the X axis. In a plan view, the laminated body 2 is, for example, symmetrical about a virtual straight line which passes through the center of the laminated body 2 and is parallel to the Y axis.

In a plan view as shown in FIG. 3, the laminated body 2 includes a first distortion imparting portion (first portion) 2a, a second distortion imparting portion (second portion) 2b, and a resonance portion (third portion) 2c.

In a plan view, the first distortion imparting portion 2a and the second distortion imparting portion 2b face each other in the Y axis direction with the resonance portion 2c interposed therebetween. In a plan view, the first distortion imparting portion 2a is protruded from the resonance portion 2c in the positive Y axis direction. In a plan view, the second distortion imparting portion 2b is protruded from the resonance portion 2c in the negative Y axis direction. The first distortion imparting portion 2a and the second distortion imparting portion 2b are provided to be integrated with the resonance portion 2c.

The first distortion imparting portion 2a and the second distortion imparting portion 2b impart distortion to the active layer 30 and polarize light generated in the active layer 30. Herein, to polarize the light is to set a vibration direction of an electric field of the light to be constant. The semiconductor layers (the first mirror layer 20, the active layer 30, the second mirror layer 40, the current constriction layer 42, the contact layer 50, the first areas 60, and the second areas 62) configuring the first distortion imparting portion 2a and the second distortion imparting portion 2b are a generation source which generates distortion to be imparted to the active layer 30. Since the first distortion imparting portion 2a and the second distortion imparting portion 2b include the first areas 60 including the plurality of oxide layers 6 and the second areas 62 including the plurality of oxide layers 16, it is possible to impart a large amount of distortion to the active layer 30.

The resonance portion 2c is provided between the first distortion imparting portion 2a and the second distortion imparting portion 2b. A length of the resonance portion 2c in the X axis direction is greater than a length of the first distortion imparting portion 2a in the X axis direction or a length of the second distortion imparting portion 2b in the X axis direction. A planar shape of the resonance portion 2c (shape when seen from the lamination direction of the first mirror layer 20 and the active layer 30) is, for example, a circle.

Herein, the length of the resonance portion 2c in the X axis direction is, for example, the greatest length along the length of the resonance portion 2c in the X axis direction. The length of the first distortion imparting portion 2a in the X axis direction is, for example, the greatest length along the length of the first distortion imparting portion 2a in the X axis direction. The length of the second distortion imparting portion 2b in the X axis direction is, for example, the greatest length along the length of the second distortion imparting portion 2b in the X axis direction.

The resonance portion 2c resonates light generated in the active layer 30. That is, the vertical resonator is formed in the resonance portion 2c.

The resin layer 70 is provided at least on side surfaces of the laminated body 2. In the example shown in FIG. 1, the resin layer 70 covers the first distortion imparting portion 2a and the second distortion imparting portion 2b. That is, the resin layer 70 is provided on the side surface of the first distortion imparting portion 2a, the upper surface of the first distortion imparting portion 2a, the side surface of the second distortion imparting portion 2b, and the upper surface of the second distortion imparting portion 2b. The resin layer 70 may completely cover the first distortion imparting portion 2a and the second distortion imparting portion 2b, or may cover some of the first distortion imparting portion 2a and the second distortion imparting portion 2b. The material of the resin layer 70 is, for example, polyimide. In the embodiment, the resin layer 70 for applying the distortion to the distortion imparting portions 2a and 2b is used, but since a configuration corresponding to the resin layer 70 is only necessary to have a function of insulating, the resin may not be used, as long as it is an insulation material.

In the example shown in FIG. 3, in a plan view, a length of the resin layer 70 in the Y axis direction is greater than a length of the resin layer 70 in the X axis direction. That is, a longitudinal direction of the resin layer 70 is the Y axis direction. The longitudinal direction of the resin layer 70 and the longitudinal direction of the laminated body 2 coincide with each other.

The first electrodes 80 are provided on the first mirror layer 20. The first electrodes 80 form ohmic contact with the first mirror layer 20. The first electrodes 80 are electrically connected to the first mirror layer 20. As the first electrodes 80, an electrode in which a Cr layer, an AuGe layer, an Ni layer, and an Au layer are laminated in this order from the first mirror layer 20 side is used, for example. The first electrodes 80 are the electrodes for injecting the current to the active layer 30. Although not shown, the first electrodes 80 may be provided on the lower surface of the substrate 10.

The second electrodes 82 are provided on the contact layer 50 (on the laminated body 2). The second electrodes 82 form ohmic contact with the contact layer 50. In the example shown in the drawing, the second electrodes 82 are also formed on the resin layer 70. The second electrodes 82 are electrically connected to the second mirror layer 40 through the contact layer 50. As the second electrodes 82, an electrode in which a Cr layer, a Pt layer, a Ti layer, a Pt layer, and an Au layer are laminated in this order from the contact layer 50 side is used, for example. The second electrodes 82 are the other electrodes for injecting the current to the active layer 30.

The second electrodes 82 are electrically connected to a pad 84. In the example shown in the drawing, the second electrodes 82 are electrically connected to the pad 84 through a lead-out wiring 86. The pad 84 is provided on the resin layer 70. The material of the pad 84 and the lead-out wiring 86 is, for example, the same as the material of the second electrodes 82.

In the above description, the AlGaAs vertical cavity surface emitting laser has been described, but GaInP, ZnSSe, InGaN, AlGaN, InGaAs, GaInNAs, or GaAsSb semiconductor materials may be used according to the oscillation wavelength, for the vertical cavity surface emitting laser according to the invention.

The vertical cavity surface emitting laser 100, for example, has the following characteristics.

In the vertical cavity surface emitting laser 100, the contact layer 50 is provided over the second mirror layer 40 of the resonance portion 2c, except for a portion over the second mirror layer 40 of the first distortion imparting portion 2a and a portion over the second mirror layer 40 of the second distortion imparting portion 2b. Accordingly, in the vertical cavity surface emitting laser 100, it is possible to decrease the parasitic capacitance. As a result, in the vertical cavity surface emitting laser 100, it is possible to obtain excellent characteristics (for example, high frequency characteristics). Hereinafter, the parasitic capacitance of the vertical cavity surface emitting laser will be described in detail.

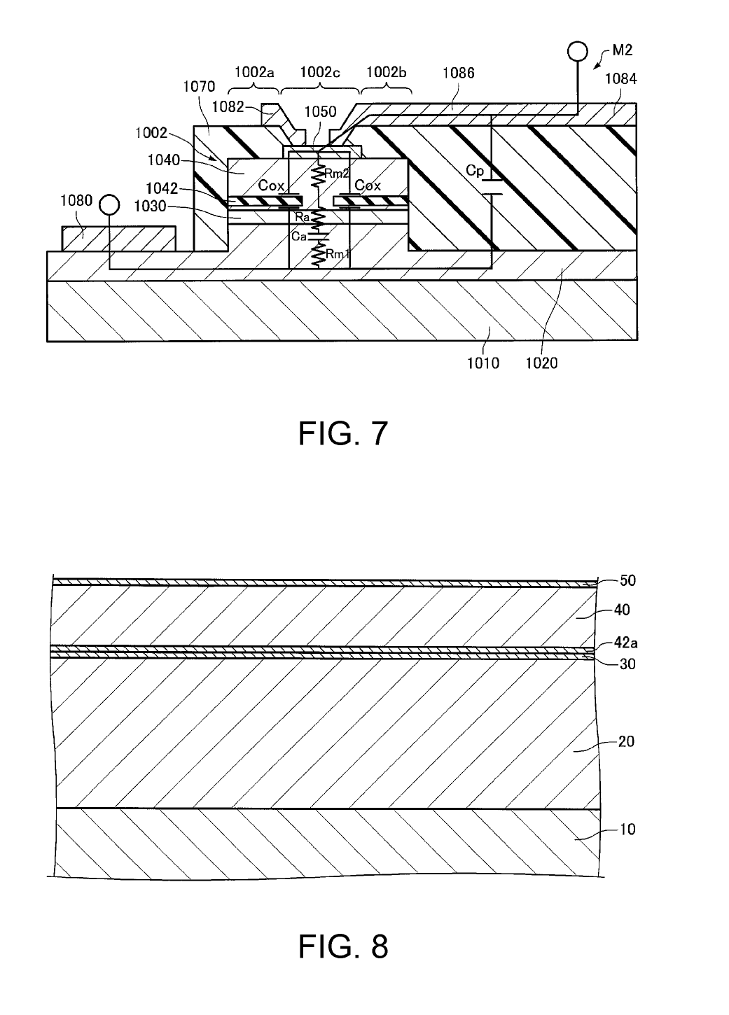

FIGS. 6 and 7 are views for illustrating the parasitic capacitance of the vertical cavity surface emitting laser. Each of a model M1 shown in FIG. 6 and a model M2 shown in FIG. 7 includes a substrate 1010, a first mirror layer 1020, an active layer 1030, a second mirror layer 1040, a current constriction layer 1042, a contact layer 1050, a resin layer 1070, a first electrode 1080, a second electrode 1082, a pad 1084, and a lead-out wiring 1086. In the models M1 and M2, the first mirror layer 1020, the active layer 1030, the second mirror layer 1040, the current constriction layer 1042, and the contact layer 1050 configure a laminated body 1002, and the laminated body 1002 includes a first distortion imparting portion 1002a, a second distortion imparting portion 1002b, and a resonance portion 1002c. In FIGS. 6 and 7, Rm1 indicates resistance of the first mirror layer 1020, Ra indicates resistance of the active layer 1030, Rm2 indicates resistance of the second mirror layer 1040, Ca indicates capacitance of the active layer 1030, Cp indicates capacitance of the pad 1084 and the lead-out wiring 1086, and Cox indicates capacitance of the current constriction layer 1042.

In model M1 shown in FIG. 6, the contact layer 1050 is provided on the entire upper surface of the second mirror layer 1040. Meanwhile, in the model M2 shown in FIG. 7, the contact layer 1050 is provided on the second mirror layer 1040 of the resonance portion 1002c, except for a portion on the second mirror layer 1040 of the first distortion imparting portion 1002a and a portion on the second mirror layer 1040 of the second distortion imparting portion 1002b. Accordingly, an area of the current constriction layer for generating the capacitance is decreased, and in the model M2, the capacitance Cox of the current constriction layer 1042 can be decreased to be smaller than the capacitance Cox of the current constriction layer 1042 of the model M1. As a result, in the model M2, it is possible to decrease the parasitic capacitance to be smaller than that of the model M1. Accordingly, also in the vertical cavity surface emitting laser 100, it is possible to decrease the capacitance of the current constriction layer 42, and to decrease the parasitic capacitance as described above.

In the vertical cavity surface emitting laser 100, the first distortion imparting portion 2a and the second distortion imparting portion 2b can impart distortion to the active layer 30 and polarize light generated in the active layer 30. Accordingly, it is possible to stably emit circularly polarized light to the gas cell through a λ/4 plate, when the vertical cavity surface emitting laser 100 is used as a light source of the atomic oscillator, for example. As a result, it is possible to increase frequency stability of the atomic oscillator. For example, when the polarization direction of the laser light emitted from the vertical cavity surface emitting laser is not stable, the light obtained through the λ/4 plate may be elliptically polarized light or a rotation direction of the circularly polarized light may be fluctuated.

### 2. Manufacturing Method of Vertical Cavity Surface Emitting Laser

Next, a manufacturing method of the vertical cavity surface emitting laser according to the embodiment will be described with reference to the drawings. FIGS. 8 to 14 are cross-sectional views schematically showing manufacturing steps of the vertical cavity surface emitting laser 100 according to the embodiment, and correspond to FIG. 5.

As shown in FIG. 8, the first mirror layer 20, the active layer 30, a layer to be oxidized 42a which is to be the oxidized current constriction layer 42, the second mirror layer 40, and the contact layer 50 are epitaxially grown in this order, on the substrate 10. As an epitaxial growth method, a metal organic chemical vapor deposition (MOCVD) method or a molecular beam epitaxy (MBE) method is used, for example.

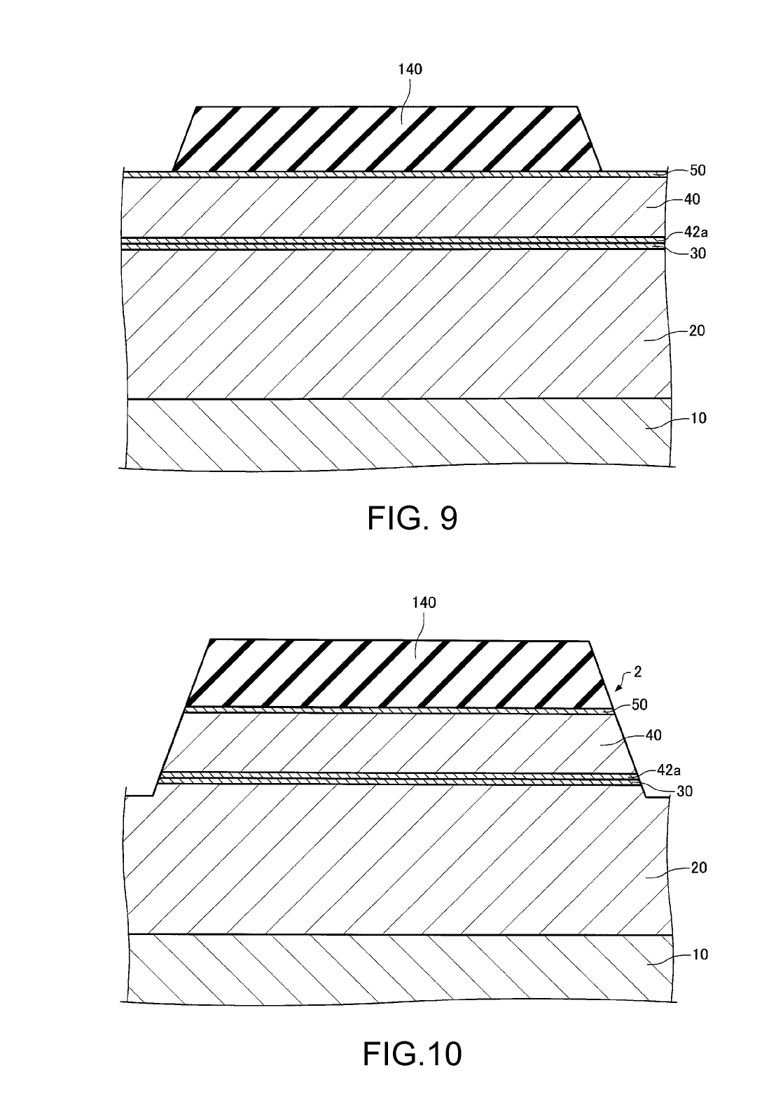

As shown in FIG. 9, a resist layer 140 having a predetermined shape is formed on the contact layer 50. The resist layer 140 is formed by photolithography.

As shown in FIG. 10, the contact layer 50, the second mirror layer 40, the layer to be oxidized 42a, the active layer 30, and the first mirror layer 20 are etched using the resist layer 140 as a mask. Accordingly, the laminated body 2 can be formed. Next, the resist layer 140 is removed by the well-known method, for example.

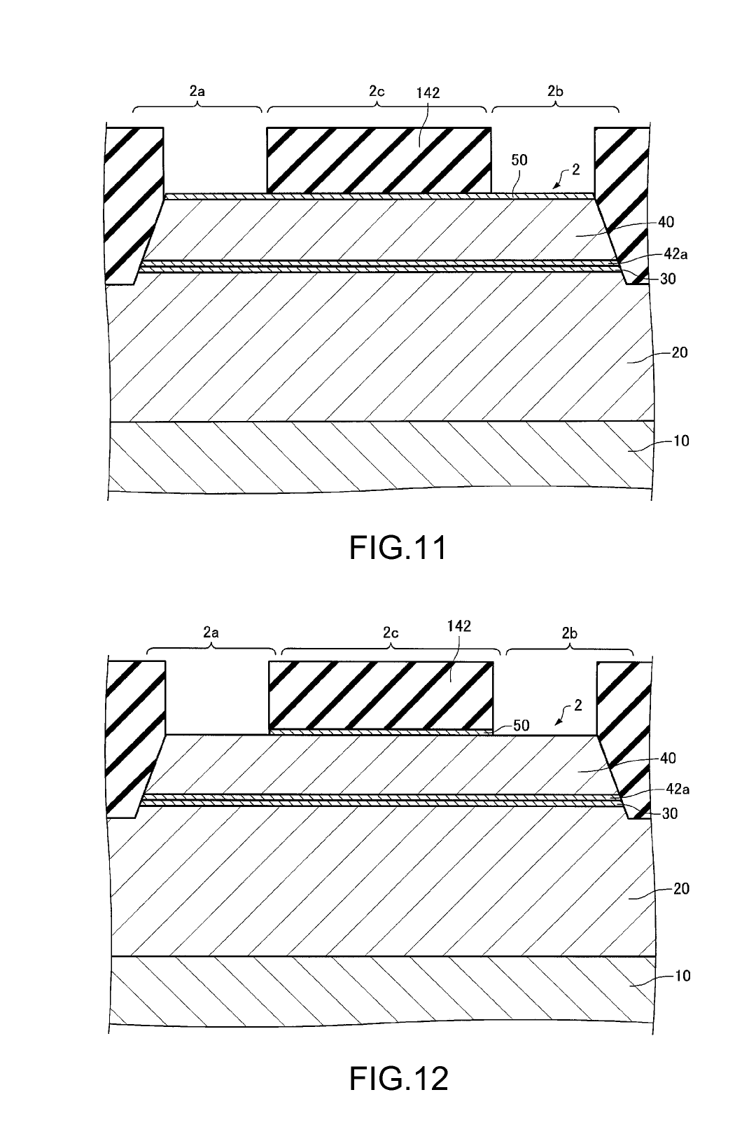

As shown in FIG. 11, a resist layer 142 having a predetermined shape is formed on the first mirror layer 20 and the contact layer 50. The resist layer 142 is formed by photolithography.

As shown in FIG. 12, the contact layer 50 is etched using the resist layer 142 as a mask. Accordingly, the contact layer 50 can be formed on the second mirror layer 40 of the resonance portion 2c, except for a portion on the second mirror layer 40 of the first distortion imparting portion 2a and a portion on the second mirror layer 40 of the second distortion imparting portion 2b. Next, the resist layer 142 is removed by the well-known method, for example.

When the high refractive index layers 24 and 44 of the mirror layers 20 and 40 are the Al_{0.12}Ga_{0.88}As layers and the low refractive index layers 26 and 46 of the mirror layers 20 and 40 are the Al_{0.9}Ga_{0.1}As layers, the low refractive index layers 26 and 46 are easily naturally oxidized, and therefore, it is preferable to expose the high refractive index layers 24 and 44 to the surface of the mirror layers 20 and 40, after removing the resist layer 142. Specifically, first, wet etching is performed with a mixed solution of, for example, NH₃, H₂O₂, and H₂O to selectively expose the low refractive index layers 26 and 46, and then wet etching is performed with a diluted HF solution, for example, to selectively expose the high refractive index layers 24 and 44. Alternatively, first, dry etching is performed with a mixed gas of SiCl₄, Cl₂, and Ar, and then the wet etching is performed with a diluted HF solution, for example, to selectively expose the high refractive index layers 24 and 44.

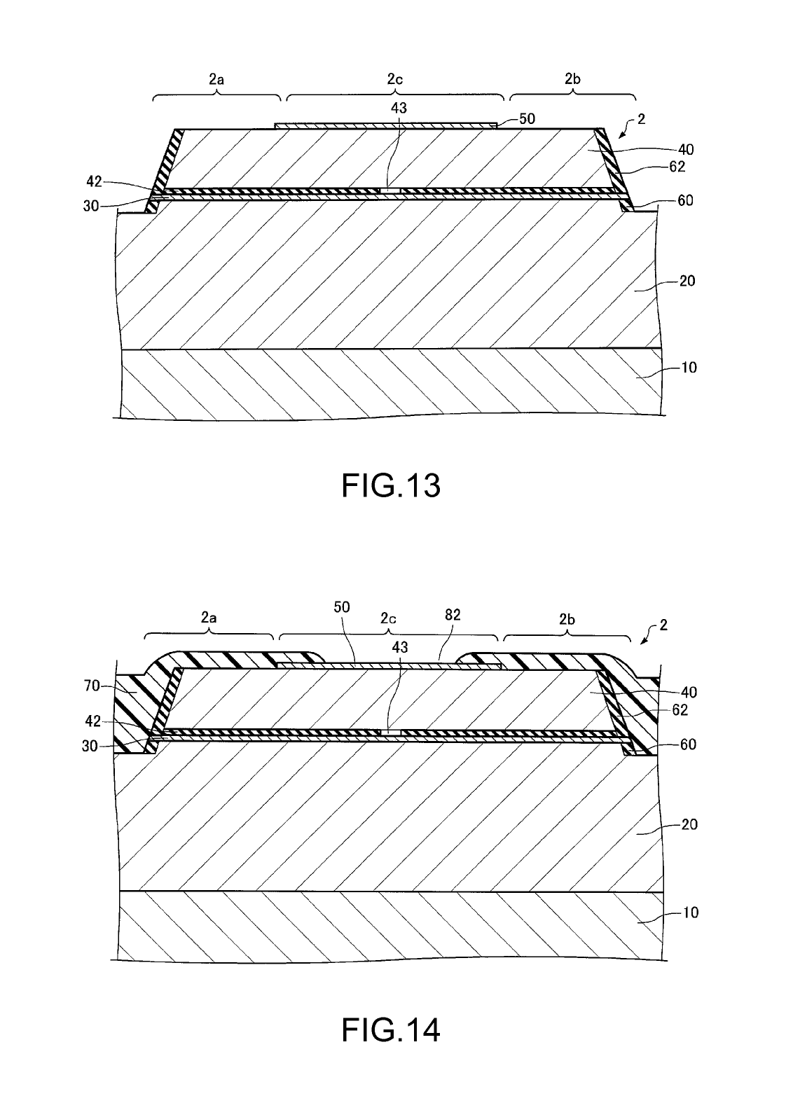

As shown in FIG. 13, the layer to be oxidized 42a is oxidized to form the current constriction layer 42. The layer to be oxidized 42a is, for example, an AlₓGa₁₋ₓAs (x≧0.95) layer. The substrate 10 on which the laminated body 2 is formed is put in a steam atmosphere at approximately 400° C., to oxidize the AlₓGa₁₋ₓAs (x≧0.95) layer from the lateral side, and accordingly the current constriction layer 42 is formed.

In the manufacturing method of the vertical cavity surface emitting laser 100, in the oxidization step, a layer configuring the first mirror layer 20 is oxidized from the lateral side to form the first area 60. A layer configuring the second mirror layer 40 is oxidized from the lateral side to form the second area 62. Specifically, due to the steam atmosphere at approximately 400° C., arsenic in the Al_{0.9}Ga_{0.1}As layer configuring the mirror layers 20 and 40 is substituted with oxygen, and the areas 60 and 62 are formed. The areas 60 and 62, for example, contract when returning the temperature from the high temperature of approximately 400° C. to the room temperature, and the upper surface 63 of the second area 62 is inclined to the substrate 10 side (see FIG. 4). The first distortion imparting portion 2a and the second distortion imparting portion 2b can apply distortion (stress) caused by the contraction of the areas 60 and 62 to the active layer 30.

As shown in FIG. 14, the resin layer 70 is formed so as to surround the laminated body 2. The resin layer 70 is formed, for example, by forming a layer formed of a polyimide resin on the upper surface of the first mirror layer 20 and the entire surface of the laminated body 2 using a spin coating method and patterning the layer. The patterning is performed by photolithography or etching, for example. Next, the resin layer 70 is hardened by performing a heating process (curing). The resin layer 70 contracts due to the heating process. In addition, the resin layer 70 contracts when returning the temperature in the heating step to a room temperature.

As shown in FIGS. 2 and 5, the second electrode 82 is formed on the contact layer 50 and the resin layer 70, and the first electrode 80 is formed on the first mirror layer 20. The electrodes 80 and 82 are, for example, formed by a combination of a vacuum vapor deposition method and a lift-off method. The order of forming the electrodes 80 and 82 is not particularly limited. In the step of forming the second electrode 82, the pad 84 and the lead-out wiring 86 (see FIG. 1) may be formed.

It is possible to manufacture the vertical cavity surface emitting laser 100 with the steps described above.

### 3. Modification Example of Manufacturing Method of Vertical Cavity Surface Emitting Laser

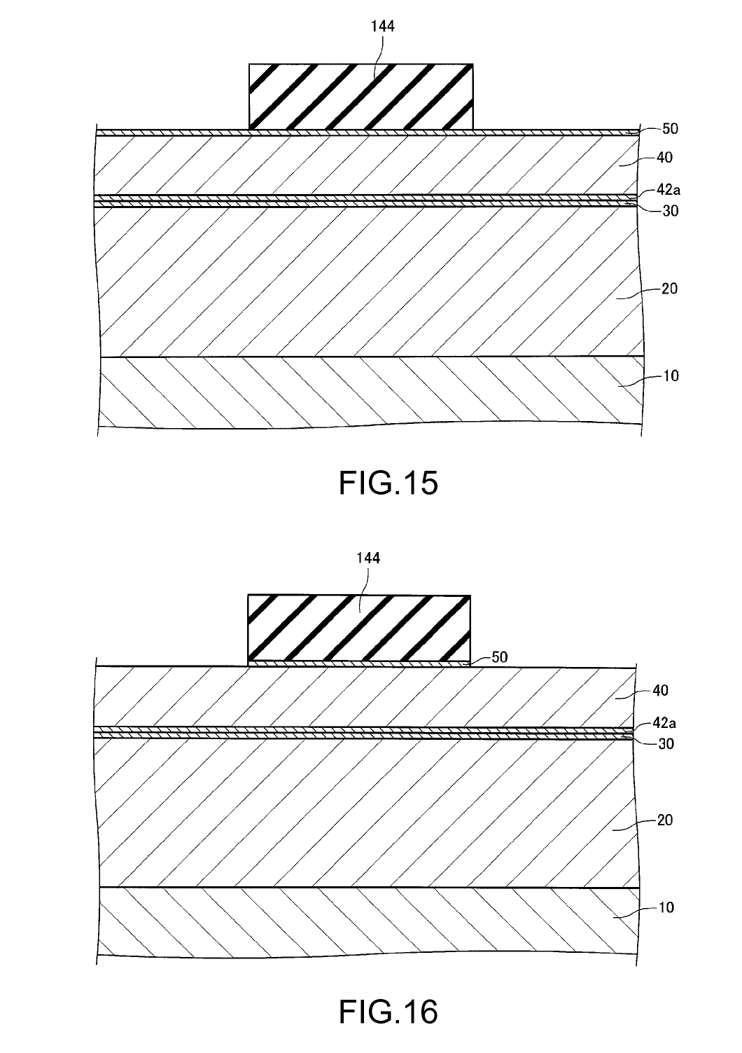

Next, a manufacturing method of the vertical cavity surface emitting laser according to a modification example of the embodiment will be described with reference to the drawings. FIGS. 15 to 18 are cross-sectional views schematically showing the manufacturing method of the vertical cavity surface emitting laser 100 according to the modification example of the embodiment, and correspond to FIG. 5. Hereinafter, the points of the manufacturing method of the vertical cavity surface emitting laser 100 according to the modification example of the embodiment different from the example of the manufacturing method of the vertical cavity surface emitting laser 100 according to the embodiment will be described, and the overlapped description will be omitted.

As shown in FIG. 8, the first mirror layer 20, the active layer 30, the layer to be oxidized 42a which is the current constriction layer 42 obtained by the oxidization, the second mirror layer 40, and the contact layer 50 are epitaxially grown in this order, on the substrate 10.

As shown in FIG. 15, a resist layer 144 having a predetermined shape is formed on the contact layer 50. The resist layer 144 is formed by photolithography.

As shown in FIG. 16, the contact layer 50 is etched using the resist layer 144 as a mask. Accordingly, the contact layer 50 can be formed on the second mirror layer 40 of the resonance portion 2c, except for a portion on the second mirror layer 40 to be the first distortion imparting portion 2a and a portion on the second mirror layer 40 to be the second distortion imparting portion 2b. Next, the resist layer 144 is removed by the well-known method, for example.

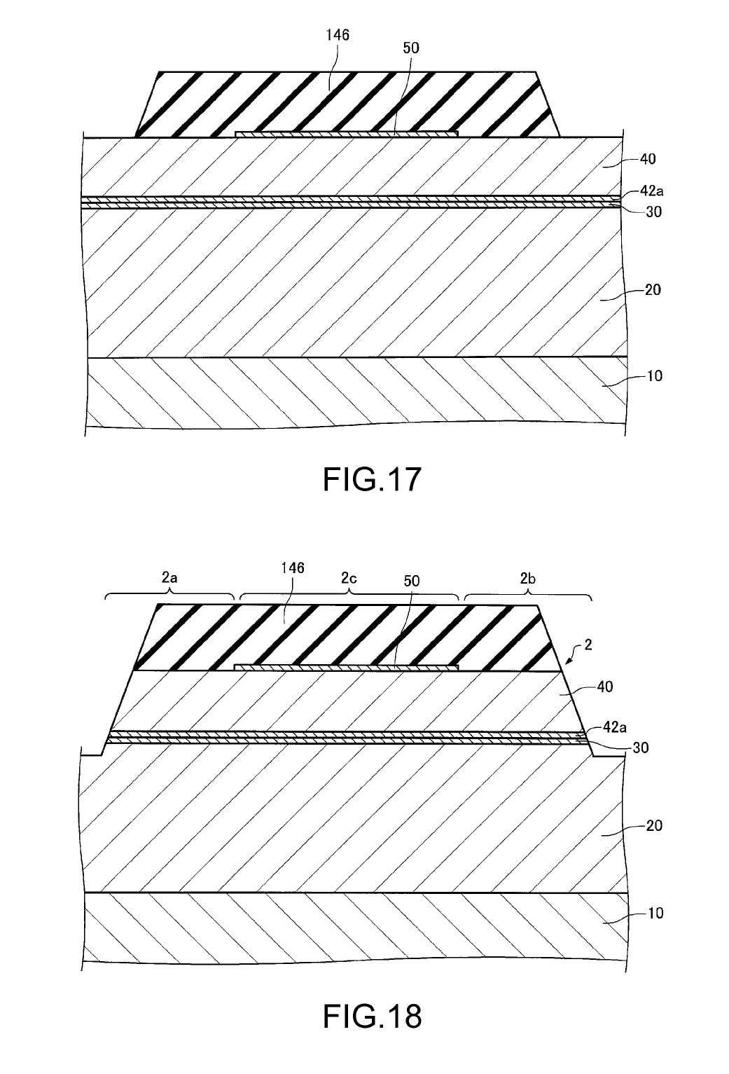

As shown in FIG. 17, a resist layer 146 having a predetermined shape is formed on the contact layer 50 and the second mirror layer 40. The resist layer 146 is formed by photolithography.

As shown in FIG. 18, the contact layer 50, the second mirror layer 40, the layer to be oxidized 42a, the active layer 30, and the first mirror layer 20 are etched using the resist layer 146 as a mask. Accordingly, the laminated body 2 can be formed. Next, the resist layer 146 is removed by the well-known method, for example.

Hereinafter, the current constriction layer 42 and the electrodes 80 and 82 are formed in the same manner as in the manufacturing method of the vertical cavity surface emitting laser 100 according to the embodiment described above.

It is possible to manufacture the vertical cavity surface emitting laser 100 with the steps described above.

### 4. Atomic Oscillator

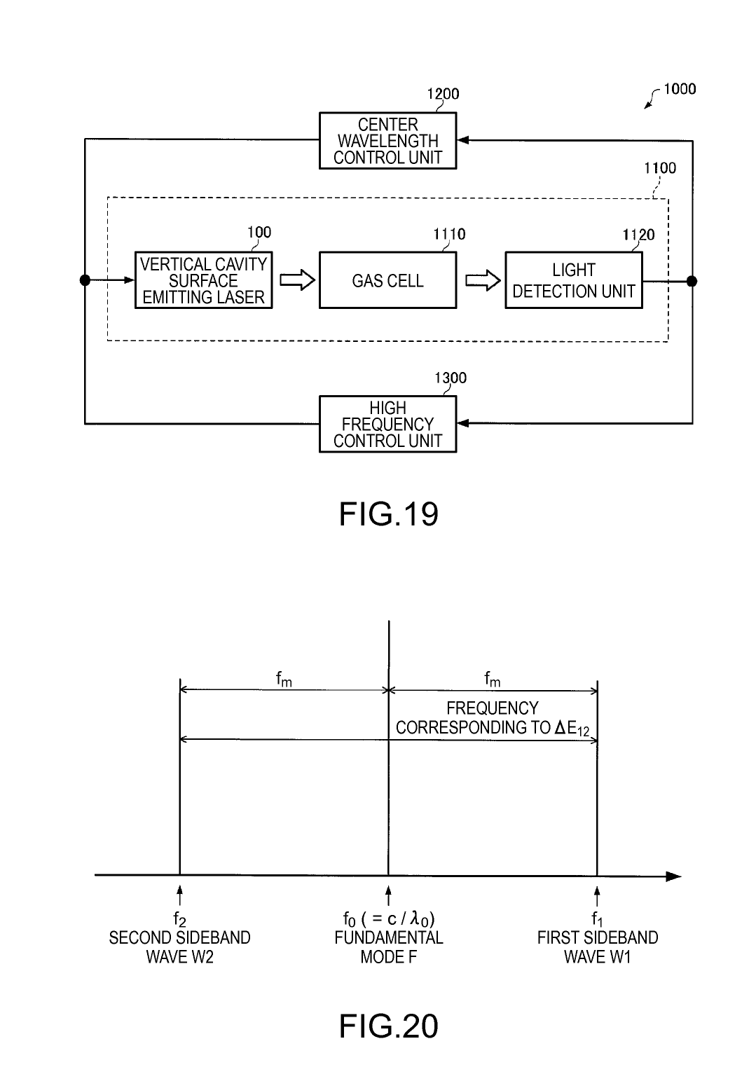

Next, an atomic oscillator according to the embodiment will be described with reference to the drawings. FIG. 19 is a functional block diagram of an atomic oscillator 1000 according to the embodiment.

As shown in FIG. 19, the atomic oscillator 1000 is configured to include an optical module 1100, a center wavelength control unit 1200, and a high frequency control unit 1300.

The optical module 1100 includes the vertical cavity surface emitting laser according to the invention (in the example shown in the drawing, the vertical cavity surface emitting laser 100), a gas cell 1110, and a light detection unit 1120.

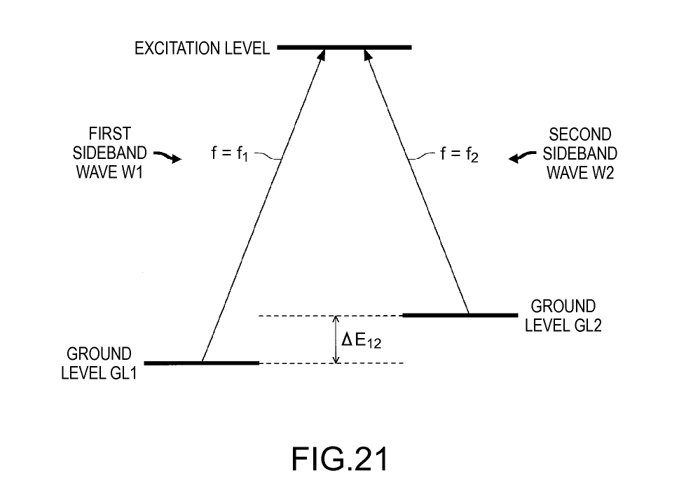

FIG. 20 is a view showing frequency spectra of light emitted by the vertical cavity surface emitting laser 100. FIG. 21 is a view showing a relationship between Λ-shaped three level models of an alkaline metal atom, a first sideband wave W1, and a second sideband wave W2. The light emitted from the vertical cavity surface emitting laser 100 includes a fundamental mode F including a center frequency f₀ (=c/λ₀: c represents velocity of light and λ₀ represents a center wavelength of laser light), the first sideband wave W1 including a frequency f₁ in an upstream sideband with respect to the center frequency f₀, and the second sideband wave W2 including a frequency f₂ in an downstream sideband with respect to the center frequency f₀, shown in FIG. 20. The frequency f₁ of the first sideband wave W1 satisfies f₁=f₀+fₘ, and the frequency f₂ of the second sideband wave W2 satisfies f₂=f₀−fₘ.

As shown in FIG. 21, a difference in frequencies between the frequency f₁ of the first sideband wave W1 and the frequency f₂ of the second sideband wave W2 coincides with a frequency corresponding to a difference in energy ΔE₁₂ between a ground level GL1 and a ground level GL2 of the alkaline metal atom.

Accordingly, the alkaline metal atom causes an EIT phenomenon to occur due to the first sideband wave W1 including the frequency f₁ and the second sideband wave W2 including the frequency f₂.

In the gas cell 1110, a gaseous alkaline metal atom (sodium atom, rubidium atom, cesium atom, and the like) is sealed in a container. When two light waves including the frequency (wavelengₜh) corresponding to the difference in energy between two ground levels of the alkaline metal atom is emitted to the gas cell 1110, the alkaline metal atom causes the EIT phenomenon to occur. For example, if the alkaline metal atom is a cesium atom, the frequency corresponding to the difference in energy between the ground level GL1 and the ground level GL2 in a D1 line is 9.19263 . . . GHz. Accordingly, when two light waves including the difference in frequency of 9.19263 . . . GHz is emitted, the EIT phenomenon occurs.

The light detection unit 1120 detects the intensity of the light penetrating the alkaline metal atom sealed in the gas cell 1110. The light detection unit 1120 outputs a detection signal according to the amount of the light penetrating the alkaline metal atom. As the light detection unit 1120, a photodiode is used, for example.

The center wavelength control unit 1200 generates driving current having a magnitude corresponding to the detection signal output by the light detection unit 1120, supplies the driving current to the vertical cavity surface emitting laser 100, and controls the center wavelength λ₀ of the light emitted by the vertical cavity surface emitting laser 100. The center wavelength λ₀ of the laser light emitted by the vertical cavity surface emitting laser 100 is minutely adjusted and stabilized, by a feedback loop passing through the vertical cavity surface emitting laser 100, the gas cell 1110, the light detection unit 1120, and the center wavelength control unit 1200.

The high frequency control unit 1300 controls so that the difference in wavelengths (frequencies) between the first sideband wave W1 and the second sideband wave W2 is equivalent to the frequency corresponding to the difference in energy between two ground levels of the alkaline metal atom sealed in the gas cell 1110, based on the detection result output by the light detection unit 1120. The high frequency control unit 1300 generates a modulation signal including a modulation frequency fₘ (see FIG. 20) according to the detection result output by the light detection unit 1120.

Feedback control is performed so that the difference in frequencies between the first sideband wave W1 and the second sideband wave W2 is extremely accurately equivalent to the frequency corresponding to the difference in energy between two ground levels of the alkaline metal atom, by a feedback loop passing through the vertical cavity surface emitting laser 100, the gas cell 1110, the light detection unit 1120, and the high frequency control unit 1300. As a result, the modulation frequency fₘ becomes an extremely stabilized frequency, and therefore, the modulation signal can be set as an output signal (clock output) of the atomic oscillator 1000.

Next, the operations of the atomic oscillator 1000 will be described with reference to FIGS. 19 to 21.

The laser light emitted from the vertical cavity surface emitting laser 100 is incident to the gas cell 1110. The light emitted from the vertical cavity surface emitting laser 100 includes two light waves (the first sideband wave W1 and the second sideband wave W2) including the frequency (wavelength) corresponding to the difference in energy between two ground levels of the alkaline metal atom, and the alkaline metal atom causes the EIT phenomenon to occur. The intensity of the light penetrating the gas cell 1110 is detected by the light detection unit 1120.

The center wavelength control unit 1200 and the high frequency control unit 1300 perform the feedback control so that the difference in frequencies between the first sideband wave W1 and the second sideband wave W2 extremely accurately coincides with the frequency corresponding to the difference in energy between two ground levels of the alkaline metal atom. In the atomic oscillator 1000, a rapid change in a light absorbing behavior when the difference in frequencies f₁−f₂ between the first sideband wave W1 and the second sideband wave W2 is deviated from the frequency corresponding to the difference in energy ΔE₁₂ between the ground level GL1 and the ground level GL2, is detected and controlled using the EIT phenomenon, and therefore it is possible to obtain an oscillator with high accuracy.

Since the atomic oscillator 1000 includes the vertical cavity surface emitting laser 100, it is possible to obtain the excellent characteristics.

The invention has configurations substantially same as the configurations described in the embodiments (for example, configurations with the same function, method, and effects, or configurations with the same object and effect). The invention includes a configuration in which non-essential parts of the configurations described in the embodiments are replaced. The invention includes a configuration having the same operation effect as the configurations described in the embodiments or a configuration which can achieve the same object. The invention includes a configuration obtained by adding a well-known technology to the configurations described in the embodiments.

The entire disclosure of Japanese Patent Application No. 2013-263470, filed Dec. 20, 2013 is expressly incorporated by reference herein.

What is claimed is:

1. A vertical cavity surface emitting laser comprising:
a substrate; and
a laminated body which is provided over the substrate,
wherein, in a plan view, the laminated body includes a first distortion imparting portion, a second distortion imparting portion, and a resonance portion which is provided between the first distortion imparting portion and the second distortion imparting portion and resonates light generated in the laminated body, and
the laminated body includes
a first mirror layer which is provided over the substrate,
an active layer which is provided over the first mirror layer,
a second mirror layer which is provided over the active layer, and
a contact layer which is provided over the second mirror layer of the resonance portion, except for a portion over the second mirror layer of the first distortion imparting portion and for a portion over the second mirror layer of the second distortion imparting portion.

2. The vertical cavity surface emitting laser according to claim 1, further comprising:
an electrode which forms ohmic contact with the contact layer.

3. The vertical cavity surface emitting laser according to claim 1,
wherein the laminated body includes a current constriction layer which is provided between the first mirror layer and the second mirror layer.

4. An atomic oscillator comprising:
the vertical cavity surface emitting laser according to claim 1.

5. An atomic oscillator comprising:
the vertical cavity surface emitting laser according to claim 2.

6. An atomic oscillator comprising:
the vertical cavity surface emitting laser according to claim 3.
